(19) United States
(12) Patent Application Publication
(10) Pub. No.: US 2007/0252177 A1
(43) Pub. Date: Nov. 1, 2007

(54) SILICON INTEGRATED CIRCUIT OPERATING AT MICROWAVE FREQUENCIES AND FABRICATION PROCESS

(75) Inventors: Robert Cuchet, Monestier De Percy (FR); Sebastien Pruvost, Froges (FR)

Correspondence Address: LOWE HAUPTMAN & BERNER, LLP, 1700 DIAGONAL ROAD, SUITE 300, ALEXANDRIA, VA, 22314, US

(73) Assignees: COMMISSARIAT A L'ENERGIE ATOMIQUE, PARIS (FR); STMICROELECTRONICS SA, MONTROUGE (FR)

(21) Appl. No.: 11/740,881

(22) Filed: Apr. 26, 2007

(30) Foreign Application Priority Data
Apr. 26, 2006 (FR) 06 03728

(51) Int. Cl. H01L 29/80

(52) U.S. Cl. 257/259

(57) ABSTRACT

The invention relates to integrated circuits for microwave applications in the millimeter wavelength range (frequencies of around 50 GHz). To improve the performance of the microwave transmission lines in the circuit, a structure of conducting vias between a transmission line and a conducting zone is proposed. The vias are formed in apertures in a benzocyclobutene layer. These apertures are larger at their base than the conducting zones. The transmission line descends into the aperture but does not come back up over the edges of the aperture. The parasitic capacitances with the substrate at the point of contact are minimized.

### FIELD OF THE INVENTION

The invention relates to integrated circuits for microwave applications in the millimeter wavelength range (frequencies of around 50 GHz).

### BACKGROUND OF THE INVENTION

These integrated circuits normally use what are called III-V semiconductor materials, that is to say compounds of an element of column III of the Periodic Table of the Elements, typically gallium but sometimes also indium, and an element of column V, typically arsenic but sometimes phosphorus. The most common material for these applications is gallium arsenide. Patent U.S. Pat. No. 5 202 752 gives an example of such an integrated circuit on a gallium arsenide substrate.

The techniques for fabricating these materials are expensive, and this is why it is endeavored to avoid having to use them, by pushing the performance of silicon-based technologies, or possibly germanium-based technologies, to the limit, these technologies being simpler and better controlled and allowing circuits to operate at ever higher frequency as the dimensions of the etched elementary features become ever smaller.

For applications at millimeter wavelengths, one drawback of using a silicon or germanium substrate is its low resistivity. Unlike gallium arsenide substrates, which are highly insulating when they are undoped (not intentionally doped), the silicon substrates on which circuits operating at millimeter wavelengths are integrated are sufficiently conducting, even lightly doped, to have an undesirable influence on the propagation of the signal in the microwave transmission circuits formed on its surface. Too conducting a substrate is a source of transmission losses as a result of the parasitic capacitances that it generates. The problem is the same for a germanium substrate.

The integrated circuit to be produced comprises, on the one hand, active elements, such as transistors, which are formed in the semiconductor, and transmission lines between these active elements. It is these transmission lines that have to be produced carefully so that their parasitic elements (parasitic capacitances, especially with the substrate, and parasitic inductances) do not disturb the distribution of the electromagnetic field lines in a manner that would degrade the electrical performance of the integrated circuit.

The transmission lines are preferably produced using, as dielectric between conductors or between a conductor and the silicon substrate, benzocyclobutene (commonly called BCB). This is because such a material exhibits very good dielectric performance at microwave frequencies. However, there remain risks of line defects especially at the point where two lines placed on two different levels have to be interconnected through the dielectric, or a line with a circuit element integrated in the actual silicon (essentially a transistor). This is because the connection vias, provided through the BCB dielectric for connecting a transmission line and an integrated element in the silicon together, are sources of microwave transmission disturbance, the more so as the silicon substrate is conducting.

To avoid parasitic capacitances, the BCB thicknesses have to be increased, but then the production of the vias between levels becomes more difficult and more space-consuming.

The invention provides a via structure for improving the performance and a corresponding fabrication process.

### SUMMARY OF THE INVENTION

The invention therefore provides a process for fabricating a microwave integrated circuit on a silicon or germanium substrate, comprising the production, on a main face of the substrate, of active elements and of at least one conducting connection zone for connecting an active element to a microwave transmission line, the deposition of at least one dielectric layer on the main face of the substrate, the production, in the dielectric layer, of an aperture baring the connection zone, and the formation, on the main face, of a conducting layer with a geometry corresponding to the transmission line, wherein the base of the aperture is larger than the connection zone bared by the aperture and wherein the geometry of the transmission line defines a line feature that descends into the aperture and covers only part of the area of the connection zone bared through the opening.

The connecting line therefore does not cover all of the bared part of the connection zone, which itself does not occupy all of the bottom of the aperture formed in the dielectric layer; the transmission line descends into the aperture but does not come back up over all the edges of the aperture as was the case in the prior art.

This structure makes it possible, as will be seen, to minimize, for a given aperture size in the dielectric layer, the conducting area (especially the area of the connection zone) which runs the risk of creating parasitic capacitances with the underlying substrate.

Thanks to this process, the characteristics of the microwave electrical connection between the transmission line and the underlying conducting zones are better controlled despite the fact that the dielectric layers, which are relatively thick, require the formation of relatively wide apertures on top of the conducting zones. The propagation losses are reduced.

The abovementioned conducting zones are in principle zones directly integrated into the semiconductor substrate at the active elements, but they may also be portions of other transmission lines resting on a dielectric layer covering the active elements. The process is the same in both cases.

The dielectric layers are preferably made of BCB. The transmission lines are preferably made of copper and the deposition process may be an electrolytic process. The conducting zones, if they are integrated into the active elements of the substrate, beneath a first BCB level, are preferably made of aluminum. The transmission lines may also be made of aluminum or an aluminum-silicon alloy.

The definition of the transmission line geometry may be effected by a two-step irradiation through two masks, one of which includes a pattern that precisely defines the transmission line on top of the BCB layer and the other of which has a pattern for opening the resist mainly remaining in the aperture and on the sidewalls, but not or practically not on the rest of the BCB layer.

The integrated circuit according to the invention, intended to operate at microwave frequencies, therefore comprises at least one silicon substrate, on the main face of which at least one active or passive element with a conducting connection zone connected to this element is integrated, a dielectric layer covering the main face of the substrate, a conducting microwave transmission line deposited on top of the dielectric layer, and an aperture through the dielectric layer on top of the connection zone, characterized in that the base of the aperture is larger than the connection zone bared through the aperture and in that the transmission line descends along an oblique slope of one sidewall of the aperture and comes into contact with the connection zone over a smaller area than the area of the connection zone bared through the aperture.

The transmission line preferably stops on the connection zone without coming back up over all the edges of the aperture formed in the dielectric layer.

### BRIEF DESCRIPTION OF DRAWINGS

Other features and advantages of the invention will become apparent on reading the following detailed description with reference to the appended drawings in which:

FIG. 1 shows a top view of a conventional conducting connection for a microwave integrated circuit between a conducting line and the active or passive elements of the integrated circuit;

FIG. 2 shows a sectional view corresponding to FIG. 1;

FIG. 3 shows a top view of a connection according to the invention;

FIG. 4 shows a corresponding section on the line IV-IV of FIG. 3;

FIG. 5 shows a section on the line V-V of FIG. 3; and

FIGS. 6 to 14 show the various steps in fabricating the conducting via structure according to the invention.

### DETAILED DESCRIPTION OF PREFERRED EMBODIMENTS

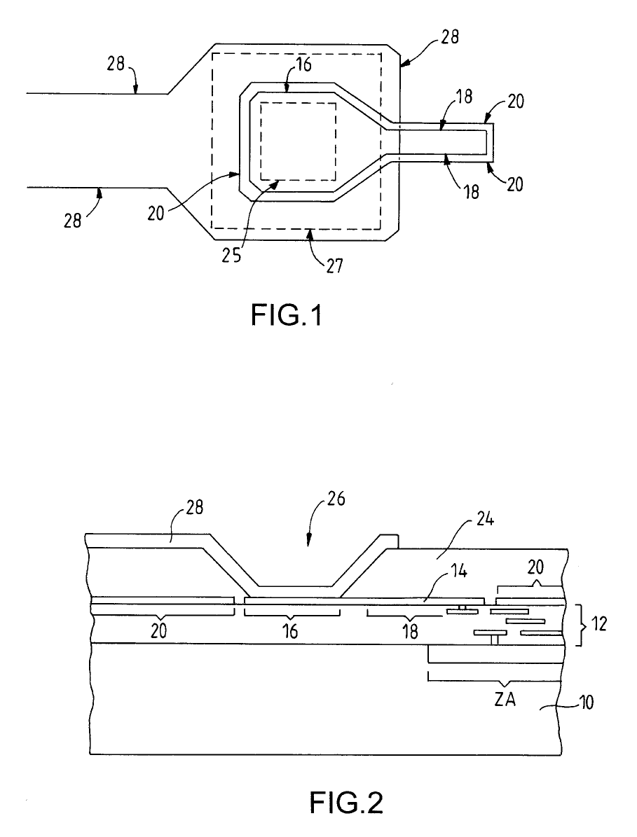

FIGS. 1 and 2 are described together. The microwave integrated circuit is produced on a main face (front face) of a silicon substrate 10. The substrate could also be made of germanium, but in the rest of the description silicon will be considered, which is a more advantageous material from the standpoint of industrial control of its use. The active or passive elements of this circuit are formed in an active zone denoted by the reference ZA (FIG. 2), which comprises both active or passive elements and interconnections over several metallic levels. The active elements are essentially transistors. The interconnection layers internal to the integrated circuit are produced by metallic levels (made of aluminum in general) embedded in insulating layers, which are usually made of silicon oxide. The various levels are connected together by conducting vias. The overall insulating layer incorporating these various metallic interconnection levels and the connection vias is denoted by the reference 12. The last interconnection level, which will be used for connecting the active or passive elements to microwave transmission lines, is denoted by the reference 14. This last level may be made of aluminum, optionally coated with a thin layer of titanium or a similar metal (for example tantalum or tungsten).

The invention relates more particularly to the connection between this last interconnection level 14 and a microwave transmission line produced in an upper level on the same main face of the integrated circuit.

In a conventional construction, such as that shown in FIGS. 1 and 2, the connection is made in the following manner: the last aluminum level 14 includes at least one conducting connection zone 16 connected to a conductor 18 on the same level, this conductor itself being connected to an active or passive element by means of the abovementioned interconnection layers. It should be noted that the conducting zone 16 and the conductor 18 may be surrounded by a ground conductor 20 in order to form a coplanar waveguide. In FIG. 1, the reference 20 denotes the outline of this ground conductor and the reference 18 denotes the outline of the conductor connected by flared edges to the essentially square conducting connection zone.

The entire semiconductor substrate is covered with a relatively thick dielectric layer 24 (of the order of 10 microns in thickness), preferably made of BCB (benzocyclobutene) which exhibits good dielectric properties at microwave frequencies. An aperture 26 is formed in the BCB above the conducting zone 16, in the middle of the latter. The bottom of the aperture 26 is occupied by the aluminum zone 16. In FIG. 1, the bottom of the aperture is represented by a dashed outline 25 having an area smaller than that of the connection zone 16. The aperture 26 therefore bares only the connection zone and even only part of said zone. The top of the aperture 26 is denoted by a dashed outline 27, which is larger than the outline 25 owing to the fact that the aperture has oblique sidewalls.

The microwave transmission line, which it is desired to electrically connect to the zone 16, is preferably a copper conductor 28 deposited on the BCB layer 24. At the connection point, the copper conductor 28 descends along the sidewalls of the aperture 26 formed in the BCB, covers the entire bared part of the conducting zone 16 and comes back up on all sides of the aperture. The conductor 28 overhangs the aperture all the way around. It is therefore wider than the aperture at the place of the latter, as the outline depicted in FIG. 1 shows.

This conventional structure means that the conducting connection zone 16 must be given a large area so that the parasitic capacitance with the substrate is high. The quality of the microwave transmission therefore suffers.

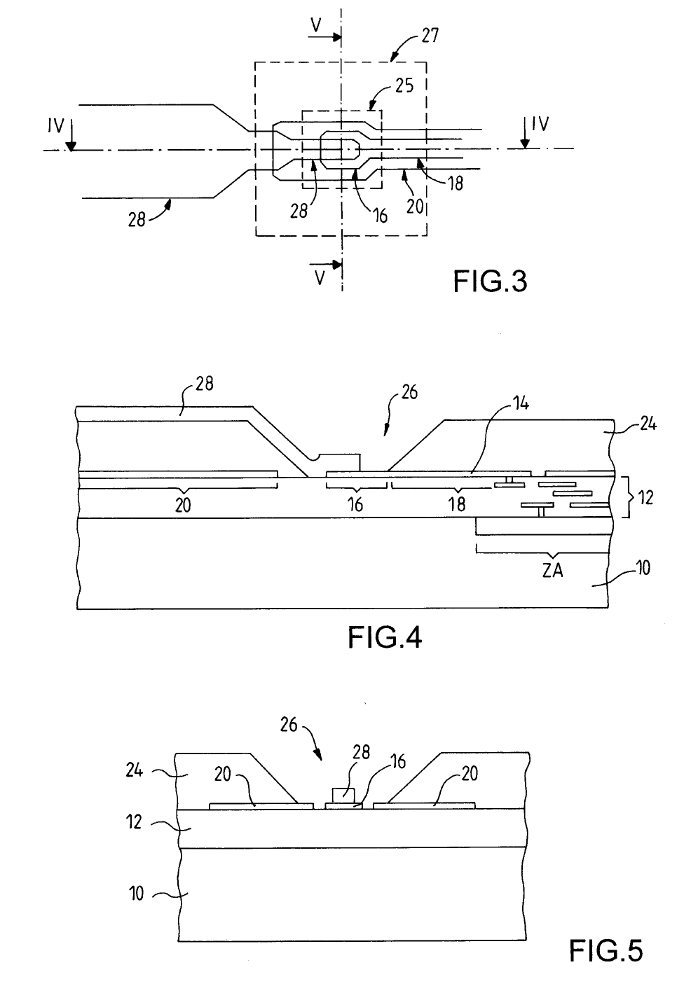

The invention proposes a different connection structure between the microwave transmission line and the active or passive elements of the integrated circuit. This connection is shown in FIG. 3 (top view), in FIG. 4 (sectional view on the line IV-IV of FIG. 3) and in FIG. 5 (sectional view on the line V-V of FIG. 3). In these figures, the same references as in FIGS. 1 and 2 are used for similar elements. FIGS. 1, 2, 3, 4 and 5 have all been drawn to the same scale by giving the base an identical square shape for the bottom of the aperture in the BCB layer (dashed outline 25) so as to bring out the reduction in size of the conducting parts which generate parasitic capacitances.

The conducting connection zone 16 now occupies a smaller area than the bottom of the aperture formed in the BCB layer.

The aperture in the BCB bares the entire conducting zone 16. It also bares part of the surface of the insulating layer 12 not covered by the aluminum layer 14. It may even partly bare the ground conductor 20 that surrounds the zone 16, as is visible in FIGS. 3 and 5.

Moreover, the copper microwave transmission line covers part of the bared area of the conducting zone 16 but not all of this bared area of the zone 16 (cf. FIG. 5) in order for the line to be correctly centered on the zone and for preventing a short circuit with the ground 20 should there be a slight misalignment.

This results in an arrangement in which the conducting area at the point of contact is particularly small, irrespective of that of the conducting zone 16 or that of the end of the transmission line present in the opening in the BCB. The coupling capacitance between these metal zones and the silicon substrate is minimized.

FIG. 3 shows how the microwave transmission line narrows before descending down to the bottom of the aperture 26 and resting on only part of the connection zone 16 without coming back up over the lateral edges of this opening, or in any case without coming back up on all sides over the lateral edges, as was the case in the prior art. In the configuration shown, the connection comes back up over none of the lateral edges.

In FIGS. 1 to 5, the additional insulating or protecting layers that cover the transmission line and the aperture formed in the BCB have not been shown. However, such layers will be provided in a completed integrated circuit structure. FIGS. 3 to 5 therefore show the integrated circuit at an intermediate stage in its fabrication.

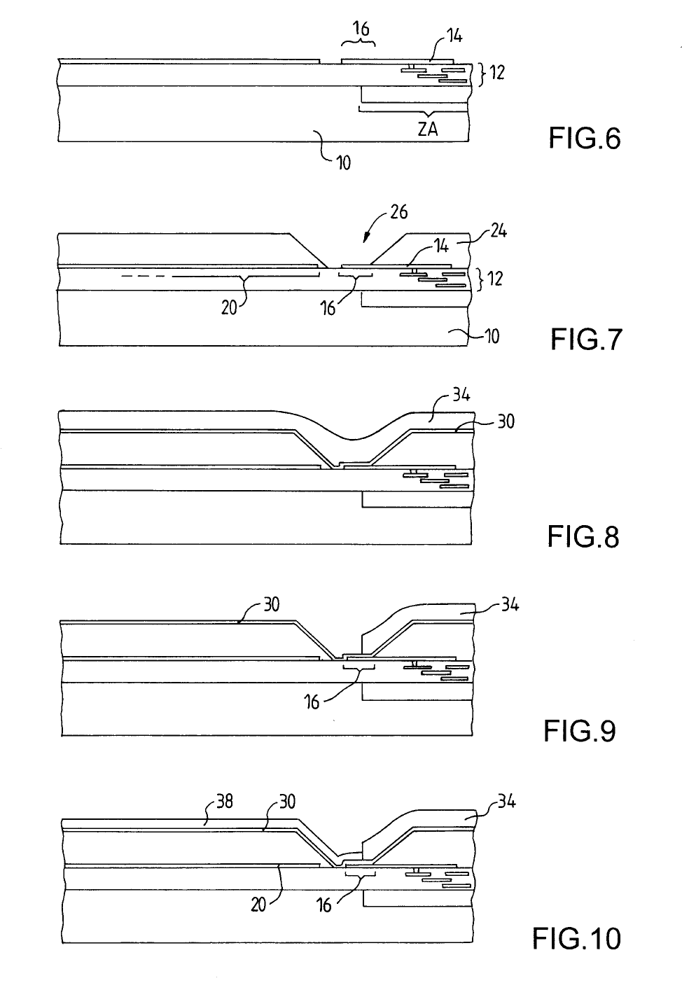

The fabrication process according to the invention, allowing an electrical connection structure as described above to be produced, will now be described with reference to FIGS. 6 to 14.

The process starts with a silicon substrate 10 on which, in an active zone ZA, the active and passive elements and their interconnections are formed by conventional steps, namely the deposition and etching of conducting, semiconductor and insulating layers, implantation of impurities, diffusions and heat treatments.

The interconnections are formed on several levels in an overall insulating layer 12 (made of silicon oxide with an overall thickness of a few microns). The connections are preferably made of aluminum or copper or a silicon-aluminum alloy or silicon-copper alloy, as are the connection vias between the various levels.

The last interconnection level is that of the layer 14, which will be used for making a connection with a microwave transmission line deposited subsequently. The layer 14 is preferably made of aluminum coated with a thin titanium layer. FIG. 6 shows the substrate at this stage in the fabrication.

In this exemplary embodiment, it will be assumed that the microwave transmission line will be used to connect a conducting zone 16 formed in the layer 14 to an external connection pad of the integrated circuit, so that the active elements are connected by a high-quality microwave line to this external connection pad.

A benzocyclobutene layer 24 is uniformly deposited, for example with a thickness of about 10 microns. An aperture 26 having oblique sidewalls is opened in this layer by a lithographic process, said aperture completely baring the zone 16 and baring part of the insulating layer 12 that surrounds it. The aperture 26 may even partly bare the ground conductor 20 formed in the layer 14 and surrounding the conducting zone 16, in a configuration as shown in FIGS. 3 to 5.

To form the aperture 26, the process may take advantage of the fact that the BCB layer is photosensitive so as to carry out direct photolithography on this layer and to remove that part of the BCB not irradiated through the mask that defines the aperture 26. This step naturally produces an aperture having oblique sidewalls.

FIG. 7 shows the substrate at this stage, with the aperture 26 having oblique sidewalls. The size of the aperture is as small as possible, given the possibilities of the photolithography for the thickness of the layer present. Typically, the BCB may be correctly opened so as to form an aperture with sides at the base of about 15 microns, this aperture having sides at the top measuring about 35 microns if the thickness of the layer is about 10 microns.

An annealing step stabilizes and crosslinks the BCB resin. A plasma cleaning step removes the undesirable residues from the bottom of the apertures 26.

A conducting sublayer 30 is then deposited by evaporation over the entire substrate. This sublayer 30 is deposited continuously in the apertures 26 and outside the apertures. It may be composed of two separate layers, for example a thin titanium layer surmounted by a thin copper layer, for example 200 Angstroms of titanium and 1000 Angstroms of copper.

Next, a photoresist layer 34 is deposited in order to define the copper electrolytic growth zones. Since the resist tends to accumulate in the apertures 26, with a greater thickness than outside the apertures, FIG. 8 shows an irregular thickness profile of the resist 34. The thickness is for example 3 microns on the BCB layer 24 and possibly up to 5 microns in the apertures 26.

The resist is then irradiated through a mask in order to define the resist parts to be retained and the resist parts to be removed. Copper will be deposited on the sublayer 30 at the places where it is no longer covered with resist.

Because of the thickness irregularity of the resist, it is preferred to irradiate it in two steps: the first step consists in irradiating the resist through an open mask mainly above the transition line pattern to be produced in the aperture 26 and on the oblique sidewall(s), but not on the main part of the transmission line, the dimensions of which must be very precise. The exposure time is adapted to the fact that the resist is thicker in the aperture and on the sidewalls. The second step consists in irradiating the resist through an open mask on top of the transmission line pattern to be produced outside the aperture (and possibly again in the aperture and on the sidewall(s)). The exposure time is shorter than in the first step. The resist is thus better irradiated at the places where it is thicker (in the bottom of the aperture and on the sidewalls) without the lateral dimensions of the transmission line being affected by an overly long irradiation.

The resist 34 is developed after these two irradiation steps (the order of which may be reversed) and is removed from the places where it was irradiated, that is to say over the entire transmission line pattern to be produced, both in the aperture 26 and outside the aperture 26. FIG. 9 shows the substrate at this stage, in which the titanium/copper sublayer is bared on the transmission line feature to be produced, and especially on part of the connection zone 16, but not on all of it.

An electrolytic growth step is then carried out (FIG. 10) in which a copper layer 38 is grown on the conductors not protected by the resist 34. For example, the layer is grown to a thickness of about 2 microns, but in any case to a thickness substantially greater than the thickness of copper of the sublayer 30. The grown layer defines the microwave transmission lines, the pattern of which had been defined by the apertures in the resist 34. It may be seen that these lines come into contact in the aperture 26 both with a portion of the bared connection zone 16 and with the insulation 12 that surrounds it. They do not come into contact with the ground lines 20 (cf. FIG. 5) even if they are flush in the aperture 26.

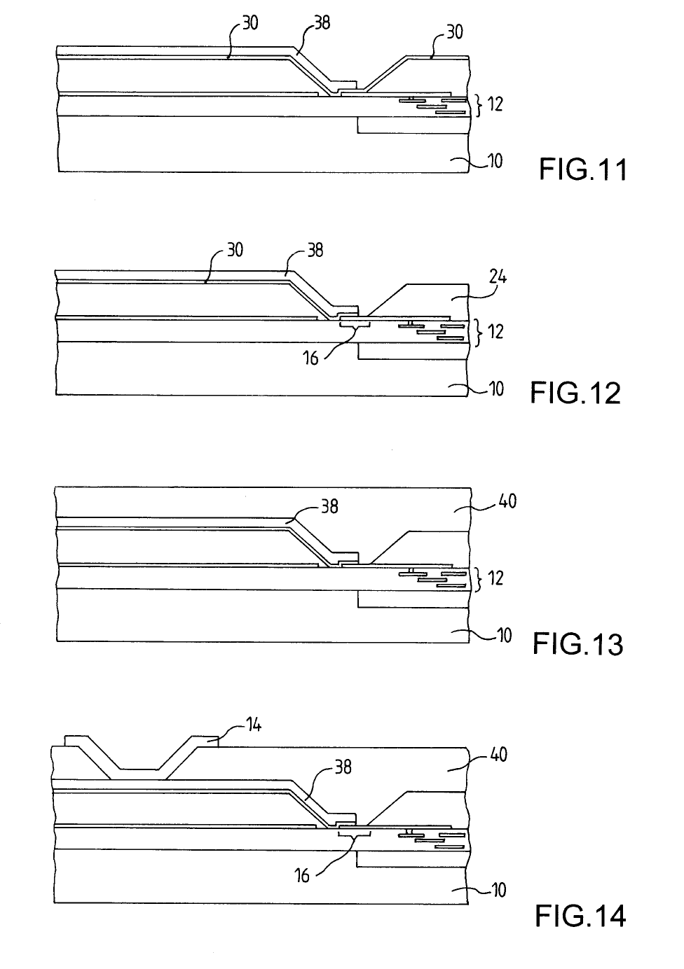

After electrolytic growth of the copper, the resist is removed (FIG. 11). The substrate is covered everywhere with the sublayer 30 and is covered by the electrolytic copper 38 on the transmission lines.

The entire substrate is lightly etched with a copper etchant for a time long enough to remove the copper of the sublayer 30 at the places where it is not covered by the electrolytic layer 38, but insufficient to remove a substantial thickness of the layer 38.

Next, the titanium layer of the conducting sublayer 30 is etched, preferably with an etchant that does not etch the copper. The BCB layer 24 is therefore bared again (FIG. 12) as are, on this layer, the transmission lines formed by the superposition of the slightly thinned electrolytic copper layer 38 and the sublayer 30 which was used as electrolysis base for it.

The conducting via according to the invention is therefore defined. The process may continue for example with the deposition of a further BCB layer 40, the opening of this layer, in order to form a via for contact with the transmission line 38, and the formation of another transmission line or external connection pads 44 by depositing and etching a metal, or by a process using electrolysis, such as that described above.

Measurements have shown that measured transmission losses of 0.4 dB per conducting via at 40 GHz could be reduced by this structure to 0.1 dB per via.

To obtain good results, the slope of the oblique sidewalls of the aperture formed in the BCB resin is preferably between 35° and 60°, preferably between 40° and 50°, for example about 45°. If the slope is too steep, it is more difficult to produce the transmission line, especially because of the photolithography steps. If it is too gentle, the parasitic capacitance between the radiofrequency line and the substrate becomes too large.

To adapt the angle to the desired value, the resist exposure time is varied, or else the distance between the photolithography mask and the substrate is varied. For example, to deposit BCB with a thickness of 10 microns, for a distance between mask and substrate of 20 microns, the BCB is exposed for 100 seconds to a lamp having a power of 16 mW/cm² and a slope of about 45° is obtained. More precisely, it is the irradiation dose received by the BCB photoresist that is important, the dose being the received power multiplied by the irradiation time. It is well understood how to produce a slope of about 45° with a photosensitive BCB resin. More abrupt sidewalls may be obtained with a non-photosensitive BCB resin.

In an alternative embodiment, the aim is to produce transmission lines made of aluminum or an aluminum-silicon alloy, for which electrolytic growth is not appropriate. After formation of the aperture 26 in the BCB layer, a different process is therefore carried out: a metallic (for example titanium) tie layer facilitating subsequent adhesion of the line is deposited; a metallic layer, made of aluminum or an aluminum-silicon alloy, forming the main material of the actual line is deposited, for example a 2 micron thick layer of aluminum is deposited; next, a resist is deposited and photoetched in a pattern defined by at least one mask; the resist remaining after development defines the transmission line pattern; the metallic layer is etched at the places where it is not protected by the resist; and the tie layer is etched at the places it is bared by removal of the metallic layer. The transmission line that remains is the superposition of the tie layer and the metallic layer.

Here again, the resist may be photoetched in two irradiation steps through two different masks, in order to properly irradiate the resist at the places where it is thicker (in the aperture 26 and on the sidewalls), while limiting the irradiation above the BCB layer so that the geometry of the transmission line remains very precisely defined.

A first mask may define the transmission line in its entirety (outside and inside the aperture, or only outside it) while a second mask may define a zone for removing the resin in the aperture and on the sidewalls.

The resist is developed after these two successive irradiation steps.

1. A process for fabricating a microwave integrated circuit on a silicon or germanium substrate, comprising the steps of:
producing, on a main face of the substrate, of active elements and of at least one conducting connection zone for connecting an active element to a microwave transmission line,
depositing at least one dielectric layer on the main face of the substrate,
producing, in the dielectric layer, of an aperture baring the connection zone, and
formatting a conducting layer with a geometry corresponding to the transmission line, wherein the base of the aperture is larger than the connection zone bared by the aperture and wherein the geometry of the conducting layer defines a line feature that descends into the aperture and covers only part of the area of the connection zone bared through the opening.

2. The process according to claim 1, wherein the dielectric layer is made of benzocyclobutene.

3. The process according claim 1, wherein the transmission line is made of copper.

4. The process according to claim 3, wherein the transmission line is formed by deposition of a conducting sublayer, deposition and irradiation of a resist through a mask, removal of the resist in a pattern defined by the mask, and electrolytic growth, on the conducting sublayer not protected by the resist, in the pattern of the transmission line to be produced.

5. The process according to claim 4, wherein the definition of the transmission line geometry is effected by a two-step irradiation through two masks, one of which has an open pattern mainly on top of the pattern of the transmission line to be produced inside the aperture and on at least one oblique sidewall of the aperture, but not on the main part of the transmission line on top of the BCB layer, and the other of which has an open pattern on top of the BCB layer in order to define the transmission line.

6. The process according to claim 1, wherein the transmission line is formed by deposition of a tie layer, which promotes subsequent adhesion of the line, then deposition of a metallic layer made of aluminum or an aluminum-silicon alloy, deposition and photoetching of a resist in a pattern defined by at least one mask, and etching of the metallic layer in order to leave behind a transmission line, and, finally, etching of the tie layer at the places where it is bared by removal of the metallic layer.

7. The process according to claim 6, wherein the definition of the transmission line geometry is effected by a two-step irradiation through two masks in order to cause greater irradiation in the aperture and on the sidewalls of the aperture than on the BCB layer.

8. An integrated circuit intended to operate at microwave frequencies, comprising:
a silicon substrate, in one main face of which at least one active or passive element with a conducting connection zone connected to this active element is integrated, a dielectric layer covering the main face of the substrate, a conducting microwave transmission line deposited on top of the dielectric layer, and an aperture through the dielectric layer on top of the connection zone, wherein the base of the aperture is larger than the connection zone bared through the aperture and in that the transmission line descends along an oblique slope of one sidewall of the aperture and comes into contact with the connection zone over a smaller area than the area of the connection zone bared through the aperture.

9. The circuit according to claim 8, wherein the transmission line stops on the connection zone without coming back up over all the edges of the aperture formed in the dielectric layer.

10. The circuit according to claim 8, wherein the dielectric layer is made of benzocyclobutene.

11. The circuit according to claim 10, wherein the connection zone is made of aluminum or copper and the transmission line is made of copper or aluminum or an aluminum-silicon alloy.

12. The circuit according to claim 8, wherein the slope of the oblique slope of the aperture sidewall is between 35° and 60°, preferably about 45°.

13. The process according claim 2, wherein the transmission line is made of copper.

14. The circuit according to claim 9, wherein the dielectric layer is made of benzocyclobutene.
